(19) United States
(12) Patent Application Publication
(10) Pub. No.: US 2016/0118935 A1
(43) Pub. Date: Apr. 28, 2016

(54) PHOTOVOLTAIC MODULES INCLUDING EXTERNAL BYPASS DIODES

(71) Applicant: SunEdison Inc., Maryland Heights, MO (US)

(72) Inventors: Jean Pascal Posbic, Frederick, MD (US); Dinesh Somabhai Amin, Clarksburg, MD (US)

(21) Appl. No.: 14/923,701

(22) Filed: Oct. 27, 2015

Related U.S. Application Data
(60) Provisional application No. 62/069,675, filed on Oct. 28, 2014.

(51) Int. Cl. H02S 40/34; H05K 7/02; G01R 31/40; H02S 30/10; H02S 40/32

(52) U.S. Cl. CPC H02S 40/34; H02S 30/10; H02S 40/32; H02S 50/00; H02S 40/345; H05K 7/02

(57) ABSTRACT

A photovoltaic (PV) module includes a laminate, a frame, a junction box, and an electronic assembly. The laminate includes a top surface, a bottom surface, and a plurality of PV cells disposed between the top surface and the bottom surface. The frame circumscribes at least a portion of the laminate. The junction box is attached adjacent to the bottom surface of the laminate and electrically coupled to the plurality of PV cells. The electronic assembly is attached adjacent to the bottom surface of the laminate and external of the junction box. The electronic assembly includes a bypass diode electrically coupled to at least one PV cell of the plurality of PV cells.

### CROSS-REFERENCE TO RELATED APPLICATION

This application claims priority to U.S. Provisional Patent Application No. 62/069,675 filed on Oct. 28, 2014, the entire disclosure of which is hereby incorporated by reference in its entirety.

### FIELD

This disclosure relates generally to photovoltaic (PV) modules with bypass diodes, more particularly, PV modules including an external electronic assembly including one or more bypass diodes.

### BACKGROUND

A PV system receives light energy, specifically solar energy, and converts the light energy to electrical energy using PV cells located within the laminate of the PV module. The PV cells are collectively coupled to a junction box to provide the output of the PV system. Bypass diodes are coupled to individual or groups of PV cells. When one or more PV cells are shaded or malfunction, the bypass diodes enable current from unaffected PV cells to bypass the affected cells with reduced power losses. Without bypass diodes, the affected PV cells may dissipate excess current as heat, which may lead to component damage.

FIG. 1 is a simplified circuit diagram of a portion of a PV system including an input 10, an output 20, a parallel PV cell 30, a bypass diode 40, and series connected PV cells 50. The input 10 is connected to another energy source such as an additional PV cell(s) (not shown). The output 20 provides an output that is a combination of the input 10 voltage and the voltage across the PV cells 30 and 50. The PV cells 30 and 50, as mentioned above, convert light energy into electrical energy. The bypass diode 40 is coupled in parallel to the PV cell 30.

Under normal operation conditions, current is produced and passes through the PV cells 30 and 50. The bypass diode 40 is reverse biased under normal conditions and substantially no current flows through the bypass diode 40. If the PV cell 30 becomes shaded or malfunctions, the PV cell 30 stops producing current (or produces a reduced current) and becomes reverse biased. The bypass diode 40 is forward biased and current flows through the bypass diode 40 rather than through the shaded PV cell 30. Absent the bypass diode 40, excess current would flow through the shaded PV cell 30 and be dissipated in the shaded PV cell 30. This dissipation in the shaded PV cell 30 may lower the efficiency of the system and may produce significant heat, which may damage the PV cell 30 and/or other portions of the system.

Current flowing through the bypass diode 40 also generates heat. The effectiveness of the bypass diode generally depends upon the diode operating within acceptable temperatures by dissipating the generated heat quickly. If the bypass diode 40 becomes too hot, the current flow through the bypass diode 40 may be reduced or the bypass diode 40 may fail. Maintaining the bypass diode at an acceptable temperature helps prevent reduced performance and life cycle of the bypass diode 40 and therefore the PV cells 30 and 50. Locating the bypass diode in proximity to other heat-generating components of the PV system may lower the rate at which the bypass diodes can dissipate heat.

This Background section is intended to introduce the reader to various aspects of the art that may be related to various aspects of the present disclosure, which are described and/or claimed below. This discussion is believed to be helpful in providing the reader with background information to facilitate better understanding of the various aspects of the present disclosure. Accordingly, it should be understood that these statements are to be read in this light, and not as admissions of prior art.

### BRIEF DESCRIPTION

According to one aspect of this disclosure, a photovoltaic (PV) module includes a laminate, a frame or a mechanical attachment device, a junction box, and an electronic assembly. The laminate includes a top surface, a bottom surface, and a plurality of PV cells disposed between the top surface and the bottom surface. The frame circumscribes at least a portion of the laminate. The junction box is attached adjacent to the bottom surface of the laminate and electrically coupled to the plurality of PV cells. The electronic assembly is attached adjacent to the bottom surface of the laminate and external of the junction box. The electronic assembly includes a bypass diode electrically coupled to at least one PV cell of the plurality of PV cells.

In another aspect of this disclosure, an electronic assembly includes a bypass diode, a printed circuit board (PCB), and a housing. The bypass diode is electrically coupled to a PV module and mounted on the PCB. The PCB includes a plurality of conductive regions. The housing has an exterior and an interior. The housing also defines an interior volume. The bypass diode is disposed within the internal volume.

Various refinements exist of the features noted in relation to the above-mentioned aspects. Further features may also be incorporated in the above-mentioned aspects as well. These refinements and additional features may exist individually or in any combination. For instance, various features discussed below in relation to any of the illustrated embodiments may be incorporated into any of the above-described aspects, alone or in any combination.

### BRIEF DESCRIPTION OF THE DRAWINGS

FIG. 1 is a simplified circuit diagram of a portion of a PV system.

FIG. 2 is a perspective view of an example PV module.

FIG. 3 is a cross-sectional view of the PV module shown in FIG. 2.

FIG. 4 is a back view of the PV module shown in FIG. 2.

FIG. 5 is a simplified circuit diagram of the PV module shown in FIG. 2.

FIG. 6 is a perspective view of an example electronic assembly.

FIG. 7 is an internal view of the electronic assembly shown in FIG. 6.

FIG. 8 is a closer view of the bypass diode and printed circuit board (PCB) shown in FIG. 7.

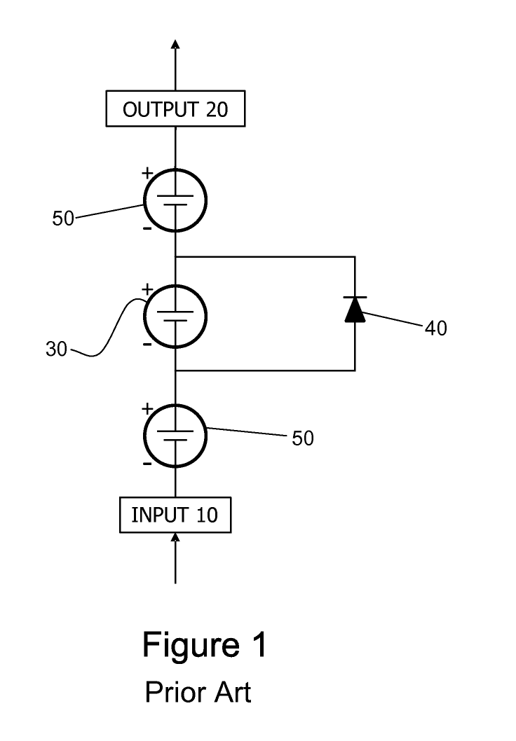

Corresponding reference characters indicate corresponding parts throughout the several views of the drawings.

### DETAILED DESCRIPTION

This disclosure relates generally to photovoltaic (PV) modules with bypass diodes. More particularly, this disclosure relates to PV modules including an external electronic assembly with bypass diodes therein. The example PV modules facilitate increased heat dissipation by the bypass diode(s) through use of an electronic assembly including bypass diode(s) external of the PV module and junction box.

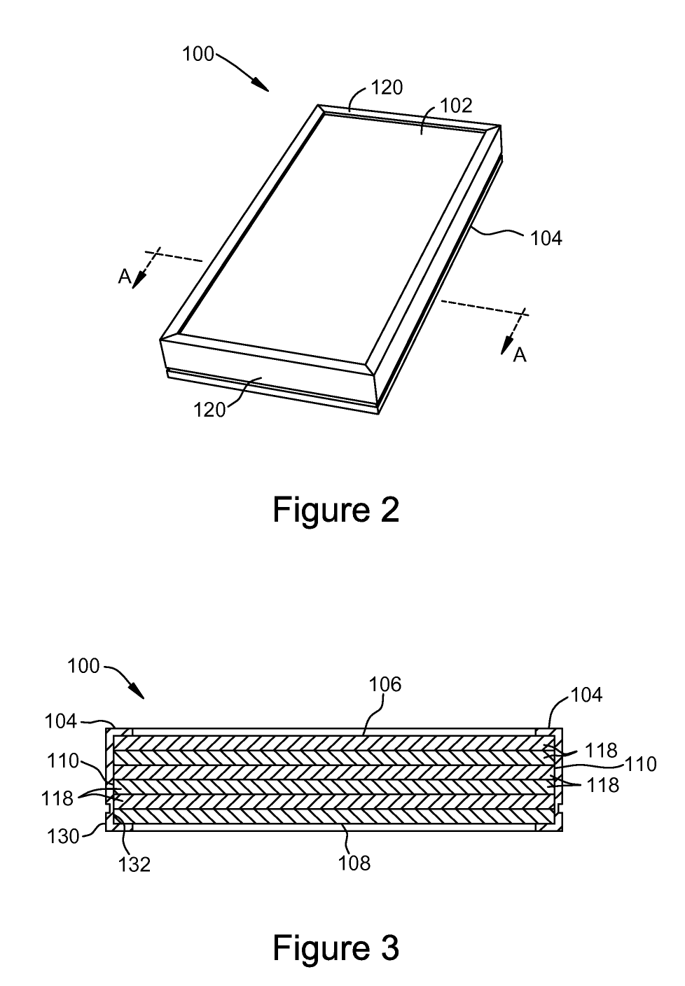

Referring initially to FIGS. 2, 3, and 4, one embodiment of a PV module is indicated generally at 100. A perspective view of the PV module 100 is shown in FIG. 2. FIG. 3 is a cross-sectional view of PV module 100 taken at line A-A as shown in FIG. 2. PV module 100 includes a laminate 102 and a frame 104 circumscribing laminate 102.

The laminate 102 includes a top surface 106 (also referred to as a sun receiving side) and a bottom surface 108 (shown in FIG. 3). Edges 110 extend between the top surface 106 and the bottom surface 108. In this embodiment, the laminate 102 is rectangular shaped. In other embodiments, the laminate 102 may have any suitable shape.

As shown in FIG. 3, the laminate 102 has a laminate structure that includes several layers 118. The layers 118 may include, for example, glass layers, non-reflective layers, electrical connection layers, n-type silicon layers, p-type silicon layers, and/or backing layers. One or more layers 118 may also include PV cells (not shown in FIGS. 2 and 3). In other embodiments, the laminate 102 may have more or fewer, including one, layers 118, may have different layers 118, and/or may have different types of layers 118.

The PV cells within the laminate 102 are electrically connected to form PV cell arrays. The PV cells are coupled together within the laminate to form the array. PV cells in an array are connected to each other in series to produce an output that is the sum of the outputs of each of the series connected PV cells. In embodiments with multiple PV cell arrays, the PV cell arrays are typically coupled to each other within a junction box, as described below. Alternatively, the PV cell arrays may be coupled together within the laminate 102.

As shown in FIG. 2, the frame 104 circumscribes the laminate 102. The frame 104 is coupled to the laminate 102, as best shown in FIG. 3. The frame 104 assists in protecting edges 110 of laminate 102. The example frame 104 includes an outer surface 130 spaced apart from the laminate 102 and an inner surface 132 adjacent to the laminate 102. The outer surface 130 is spaced apart from and substantially parallel to the inner surface 132. In the example embodiment, the frame 104 is made of aluminum. More particularly, in some embodiments, the frame 104 is made of 6000 series anodized aluminum. In other embodiments, the frame 104 may be made of any other suitable material providing sufficient rigidity including, for example, rolled or stamped stainless steel, plastic, or carbon fiber.

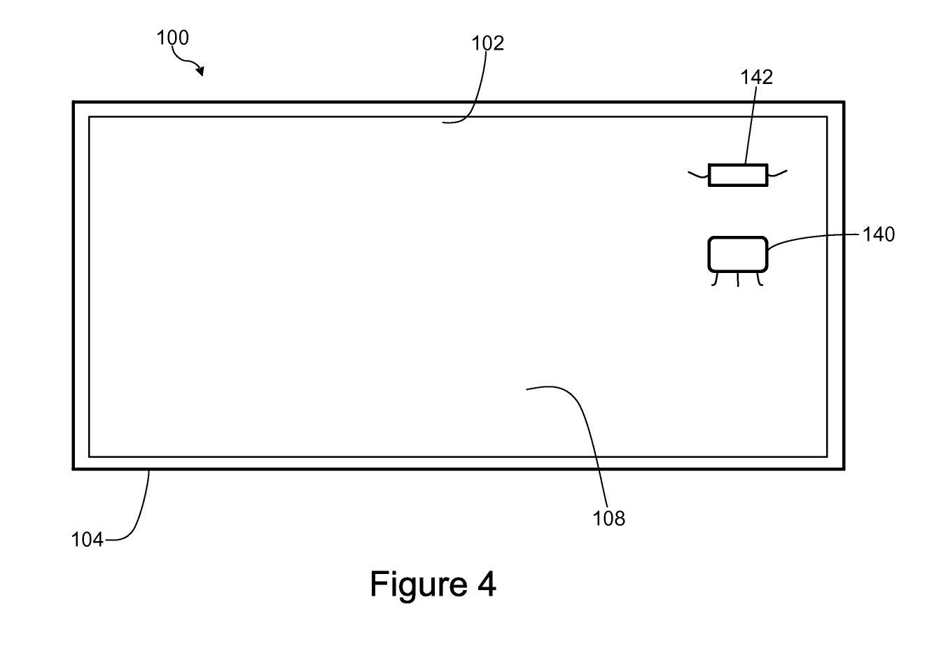

FIG. 4 is a plan view of the bottom surface 108 of the PV module 100. The PV module 100 includes the junction box 140 and an electronic assembly 142 disposed adjacent the bottom surface 108. The junction box 140 is attached to the laminate 102. In other embodiments, the junction box 140 is attached to the frame 104. In some embodiments, the PV module 100 includes structural features to facilitate a mechanical connection to the junction box 140 and/or the electronic assembly 142. Examples include holes for screws, a ledge on the frame 104 or the laminate 102, or a structure to be paired with a mating structure on the components as described below.

The electronic assembly 142 is mechanically attached to the laminate 102. In other embodiments, the electronic assembly 142 is attached to the frame 104 or the junction box 140. The junction box 140 may include structural features such as screw holes to pair with mating structures of the electronic assembly 142 to facilitate a mechanical connection.

Although a single electronic assembly 142 is shown in FIG. 4, the PV module 100 may include any suitable number of electronic assemblies 142. In some embodiments, the PV module 100 includes multiple electronic assemblies 142. The electronic assembly 142 includes at least one bypass diode (not shown in FIG. 4). In other embodiments, the electronic assembly 142 includes multiple bypass diodes. The bypass diode is electrically coupled to at least one PV cell array in PV module 100.

The bypass diode is coupled to the PV cell(s) such that under normal operating conditions in which all PV cells are forward biased, the bypass diode is reverse biased to force current to flow through the parallel PV cell array. When at least one parallel PV cell is reverse biased due to shading or other malfunctions, the polarity of the bypass diode is forward biased and current flows through the bypass diode to protect the PV cell(s) from generating excessive heat and causing component failure. In other embodiments, alternative methods of directing current away from malfunctioning PV cells, such as with a switching component, are implemented.

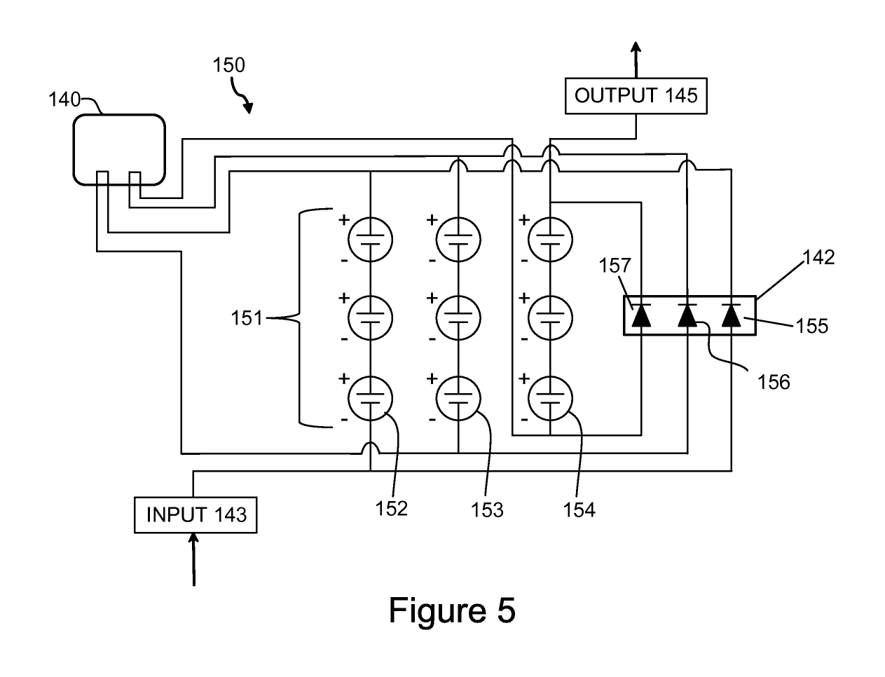

FIG. 5 is a simplified circuit diagram of the PV module 100 including an input 143, an output 145, a group of PV cell arrays 151, the junction box 140, and the electronic assembly 142. In the example embodiment, the group of PV cell arrays 151 includes PV cell arrays 152, 153, and 154. In other embodiments the group of PV cell arrays 151 includes any suitable number of more or fewer PV cell arrays. PV cell arrays 152, 153, and 154 each include three PV cells. PV cell arrays in other embodiments can include any number of PV cells.

The junction box 140 electrically couples the PV cell arrays 152, 153, and 154 in series external to the laminate 102 to allow for ease of access and safe handling during manufacturing and repairing the PV module 100. Alternatively, or additionally, PV cell arrays may be connected in parallel within the junction box 140. Additionally, the input 143 and/or the output 145 may be housed within the junction box 140. In some embodiments, the junction box 140 contains additional circuitry such as, but not limited to, arc suppression, monitoring, and inverters (not shown) to perform complimentary tasks.

The electronic assembly 142 includes bypass diodes 155, 156, and 157. In other embodiments, the electronic assembly 142 may include any suitable number of bypass diodes. Each bypass diode 155, 156, and 157 is connected in parallel with a respective PV cell array. Alternatively, each bypass diode 155, 156, and 157 may be connected in parallel with a single PV cell or a portion of a PV cell array. In the example embodiment, the bypass diode 155 is connected to the PV cell array 152, the bypass diode 156 is connected to the PV cell array 153, and the bypass diode 157 is connected to the PV cell array 154. In the example embodiment, the bypass diodes 155, 156, and 157 are Schottky diodes. Alternatively, diodes 155, 156, and 157 may be any other suitable diode or other component suitable for use as a bypass for one or more PV cells.

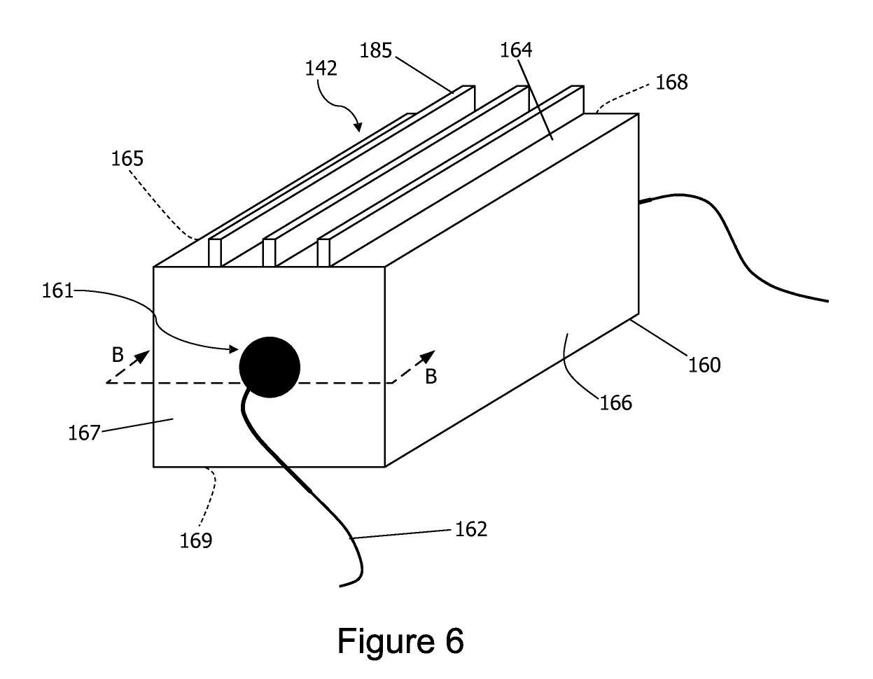

FIG. 6 is a perspective view of the electronic assembly 142. Electronic assembly 142 includes an enclosure 160, electrical conductors 162, and bypass diodes 155, 156, and 157 (not shown in FIG. 6). Alternatively, the electronic assembly 142 may include less than all of the bypass diodes. In the example embodiment, the enclosure 160 is composed of a poly-carbonate material. In other embodiments, the enclosure 160 can be made of alternative materials that provide a suitable rigid structure. The enclosure 160 includes a top 164, sides 165 and 166, ends 167 and 168, and a bottom 169 that define an interior volume. In some embodiments, the enclosure 160 includes one or more structural features to facilitate a secure mechanical connection to the PV module 100 such as a mating structure or rubber pads on the bottom of the enclosure 160.

In some embodiments, the enclosure 160 includes one or more heat sink structures to facilitate quick heat dissipation from the enclosure and the bypass diode(s) disposed therein. Examples of the heat sink structures include, but are not limited to, heat sink fins, a copper contact in thermal communication with a coolant such as water, and a thermal compound to spread heat across a surface area, and the like. In the illustrated embodiment, the top 164 of the enclosure 160 includes a plurality of heat sinks fins 185.

The enclosure 160 includes holes 161 through which the conductors 162 exit/enter the enclosure 160 to provide an electrical connection to the bypass diodes 155, 156, and 157. The conductors 162 extend outwardly from the electronic assembly 142. Alternatively, the conductors 162 terminate in proximity to the outer surface of the electronic assembly 142 to be connected to other conductors (not shown).

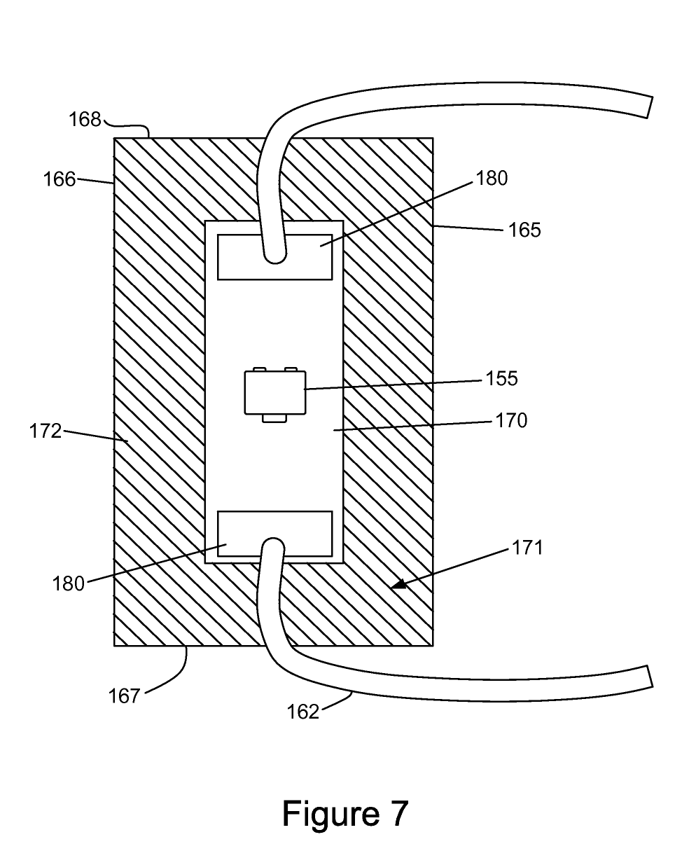

FIG. 7 is a cross sectional view of the electronic assembly 142 taken along the line B-B in FIG. 6. A printed circuit board (PCB) 170 is disposed in the interior volume 171 of the enclosure 160. The bypass diode 155 is mounted on the PCB 170. For clarity, a single PCB 170 and a single bypass diode 155 are shown in FIG. 7. The enclosure 160 may include structures (not shown) to provide additional mechanical support to the PCB 170 and the conductors 162.

The PCB 170 is a circuit board including integrated conductors (not shown) and electrically conductive regions 180 to facilitate coupling electrical components, such as the bypass diode 155 and the conductors 162, to each other.

A potting compound (potant) 172 is used to provide protection to the bypass diode 155 and the PCB 170 from factors such as vibration, shock, and moisture while allowing heat to dissipate outwardly. The potant 172 substantially fills the portion of the interior volume 171 that is not occupied by the PCB 170, the components mounted on PCB 170 (such as bypass diode 155), and the conductors 162. In the example embodiment, the potant 172 is a silicone-based potant. In other embodiments, the potant 172 is composed of any other suitable potant material.

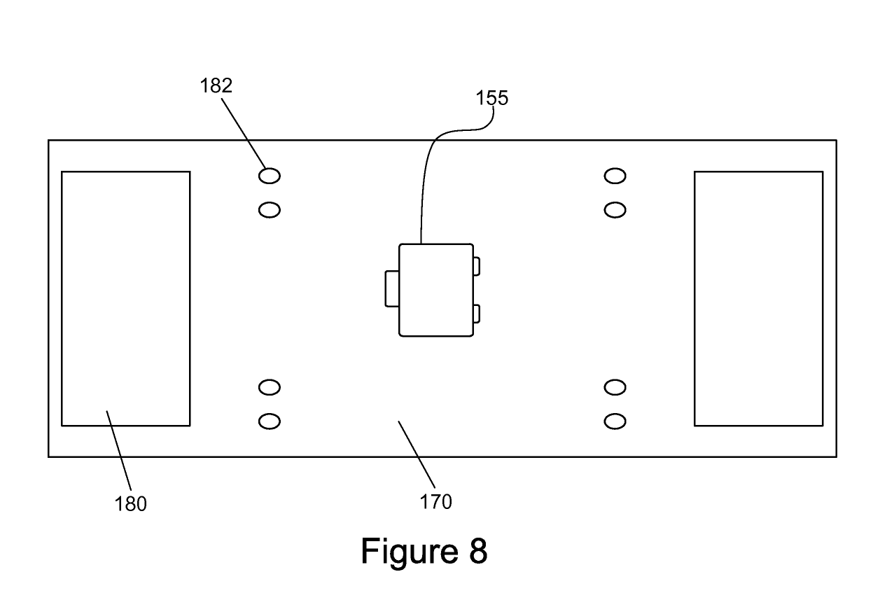

FIG. 8 is a closer view of the bypass diode 155 and the PCB 170 shown in FIG. 6. The bypass diode 155 is attached to the PCB 170 using surface mount soldering. Alternatively, the bypass diode 155 may be through-hole mounted, or coupled to the PCB 170 using other suitable methods of attachment. The PCB 170 includes electrically conductive regions for components other than the bypass diode 155. The electrically conductive regions include conductor pads 180 and through-holes 182 for complimentary circuitry. In order to electrically couple the electrically conductive regions to each other, the PCB 170 includes integrated conductors coupled to each electrically conductive region. The integrated conductors couple the bypass diode 155 to each conductor pad 180. The conductor pads 180 couple to the conductors 162 in order to couple the bypass diode 155 to the PV module 100.

The through-holes 182 couple circuitry (not shown) providing complementary functions to the electronic assembly 160. The circuitry can include, but is not limited to, an inverter, arc suppression circuitry, and/or monitoring circuitry. The through-holes 182 are coupled by the integrated conductors to the conductor pads 180 and the bypass diode 155. In other embodiments, the PCB 170 includes alternative configurations of the electrically conductive regions and integrated conductors to provide connections to electrical components.

The rate of heat dissipation of the bypass diode 155 is improved over some known systems by attachment of the electronic assembly 142 external to the laminate 102 and the junction box 140. By isolating the bypass diode 155 from other heat-producing components, the bypass diode 155 is capable of dissipating heat at an improved rate and subsequently maintains a temperature within an optimal operation range. The improved heat dissipation rate may lead to an improved lifetime of the bypass diode 155. The electronic assembly may facilitate reduce the time needed to install and maintain bypass diodes in a PV module. To an owner of PV module 100, the addition of the electronic assembly 142 may lead to cost savings by decreasing the need for replacement bypass diodes 155, decreasing labor time needed to install and repair the electronic assembly 142, and lowering the risk of damaging other components during installation and repair.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

What is claimed is:

1. A photovoltaic (PV) module comprising:
a laminate including a top surface, a bottom surface, and a plurality of PV cells disposed between the top surface and the bottom surface; and
a frame circumscribing at least a portion of the laminate; and
a junction box attached adjacent to the bottom surface of the laminate, the junction box electrically coupled to the plurality of PV cells; and
an electronic assembly attached adjacent to the bottom surface of the laminate and external of the junction box, the electronic assembly including a bypass diode electrically coupled to at least one PV cell of the plurality of PV cells.

2. A PV module in accordance with claim 1, wherein the at least one PV cell comprises a plurality of PV cells electrically connected in series.

3. A PV module in accordance with claim 1 further including a plurality of conductors extending from the laminate and coupled to the at least one PV cell and the electronic assembly.

4. A PV module in accordance with claim 3, wherein the electronic assembly is coupled in parallel with at least one of the plurality of PV cells via the conductors.

5. A PV module in accordance with claim 3, wherein the electronic assembly includes a printed circuit board (PCB) and the bypass diode is mounted on the PCB.

6. A PV module in accordance with claim 5, wherein the PCB includes a plurality of conductive regions electrically coupled to the at least one PV cell via the plurality of conductors, the bypass diode coupled across at least two of the plurality of conductive regions.

7. A PV module in accordance with claim 6, wherein the electronic assembly includes a component selected from a group of electronic circuitry consisting of an inverter, an arc suppression circuit, and a monitoring circuit, wherein the component is electrically coupled to at least one of the plurality of conductive regions.

8. A PV module in accordance with claim 1, wherein the electronic assembly is mechanically attached to the frame.

9. A PV module in accordance with claim 1, wherein the electronic assembly is mechanically attached to the exterior of the junction box.

10. A PV module in accordance with claim 1, wherein the electronic assembly is mechanically attached to the laminate.

11. A PV module in accordance with claim 1, wherein the electronic assembly comprises a housing having an exterior and an interior, and defining an internal volume, wherein the bypass diode is disposed within the internal volume.

12. A PV module in accordance with claim 11, wherein the electronic assembly includes a potant disposed within the interior of the housing.

13. A PV module in accordance with claim 1 further comprising additional electronic assemblies attached adjacent to the bottom surface of the laminate and external of the junction box, the electronic assemblies each including a bypass diode electrically coupled to at least one PV cell of the plurality of PV cells.

14. An electronic assembly comprising:
a bypass diode configured to electrically couple to a PV module; and
a printed circuit board (PCB), wherein the PCB includes a plurality of conductive regions, wherein the bypass diode is mounted on the PCB; and
a housing having an exterior and interior, and defining an internal volume, wherein the bypass diode is disposed within the internal volume.

15. An electronic assembly in accordance with claim 14, wherein the bypass diode coupled across at least two of the plurality of conductive regions.

16. An electronic assembly in accordance with claim 14, wherein the electronic assembly includes a component selected from a group of electronic circuitry consisting of an inverter, an arc suppression circuit, and a monitoring circuit, wherein the component is electrically coupled to at least one of the plurality of conductive regions.

17. An electronic assembly in accordance with claim 14, wherein the exterior of the housing includes heat sink fins.

18. An electronic assembly in accordance with claim 14, wherein the electronic assembly includes a potant disposed within the interior of the housing.

19. An electronic assembly in accordance with claim 18, wherein the potant is a silicone-based potant.

20. An electronic assembly in accordance with claim 18, wherein the internal volume of the housing is substantially filled by the bypass diode and the potant.
